(19) United States
(12) Patent Application Publication
(10) Pub. No.: US 2026/0123166 A1
(43) Pub. Date: Apr. 30, 2026

(54) Dual Oxide Moisture Barrier

(71) Applicants: Swift Solar Inc., San Carlos, CA (US); Alliance for Sustainable Energy, LLC, Golden, CO (US)

(72) Inventors: Giles Eperon, Arvada, CO (US); Daniel Martinez, Wheat Ridge, CO (US); Axel Finn Palmstrom, Golden, CO (US)

(21) Appl. No.: 19/188,905

(22) Filed: Apr. 24, 2025

Related U.S. Application Data
(60) Provisional application No. 63/648,135, filed on May 15, 2024.

(51) Int. Cl. H10K 30/88; H10K 30/40; H10K 30/57; H10K 71/00; H10K 85/50

(52) U.S. Cl. CPC H10K 30/88; H10K 30/40; H10K 30/57; H10K 71/00; H10K 85/50

(57) ABSTRACT

Perovskite solar cells with a dual oxide moisture barrier deposited by atomic layer deposition are described, where a first oxide layer is deposited over the solar cell with a water oxidizer and a second oxide layer is deposited over the first oxide layer with an ozone oxidizer.

### RELATED APPLICATIONS

This application claims the benefit of priority of U.S. Provisional Application No. 63/648,135 filed May 15, 2024 which is incorporated herein by reference.

### CONTRACTUAL ORIGIN

This invention was made with government support under Contract No. DE-AC36-08GO28308 awarded by the Department of Energy. The government has certain rights in the invention.

### BACKGROUND

### Field

Embodiments described herein relate to solar cells, and more particularly to moisture barriers.

### Background Information

Photovoltaic cells, also referred to as solar cells, are devices that convert radiant photo energy into electrical energy. While monocrystalline solar cells are dominant in the current solar industry and offer some of the highest efficiencies and lifetimes, thin-film solar cells are gaining more attention due to the potential to implement economical in-line processes of deposition and patterning. Furthermore, some thin-film solar cells can be flexible with potential applications on curved surfaces, mobile devices, or other components. One such emerging thin-film technology is perovskite solar cells. Like other solar cells, perovskite solar cells can be sealed by a solar panel encapsulant to protect against weather related factors (e.g., moisture, oxidation, extreme temperature, etc.) and ensure the longevity and durability of the solar panel.

### SUMMARY

Embodiments describe solar cells and methods of fabrication. In an embodiment, a solar cell may include a moisture barrier with a first oxide layer formed over the solar cell and a second oxide layer formed over the first oxide layer. In an embodiment, the first oxide layer may be formed by oxidizing a precursor material with a first oxidizer, where the first oxidizer may include water. Further, the second oxidizer layer may be formed by oxidizing the precursor with a second oxidizer, where the second oxidizer may include ozone.

### BRIEF DESCRIPTION OF THE DRAWINGS

FIG. 1 is a schematic top view illustration and circuit diagram of a solar cell module in accordance with embodiments.

FIG. 2A is an illustrative diagram of a tandem solar cell stack-up in accordance with an embodiment.

FIG. 2B is a schematic perspective view illustration of a tandem solar cell stack-up in accordance with an embodiment.

FIG. 3 is a process flow of a method for forming an exemplary solar cell with a dual oxide moisture barrier in accordance with an embodiment.

FIG. 4A-4B are schematic cross-sectional side view illustrations of a method for forming an exemplary solar cell with a dual oxide moisture barrier in accordance with an embodiment.

FIG. 5A is a graphical representation of power conversion efficiency tests for perovskite solar cells that include single oxide moisture barrier layers.

FIG. 5B is a graphical representation of damp heat tests for perovskite solar cells that include single oxide moisture barrier layers.

FIG. 6A is a graphical representation of power conversion efficiency tests for perovskite solar cells that include a dual oxide moisture barrier in accordance with an embodiment.

FIG. 6B is a graphical representation of damp heat tests for perovskite solar cell that include dual oxide moisture barrier in accordance with an embodiment.

FIGS. 7A-7C are photographs of perovskite solar cell specimens with single oxide moisture barrier and dual oxide moisture barrier after a damp heat test.

FIGS. 8A-8C are graphical representations of time-of-flight secondary ion mass spectrometry depth profiles for single oxide moisture barrier and dual oxide moisture barrier in accordance with an embodiment.

FIGS. 9A-9B are graphical representations of time-of-flight secondary ion mass spectrometry count ratios for single oxide moisture barrier and dual oxide moisture barrier in accordance with an embodiment.

FIGS. 10A-10D are graphical representations of variable angle spectroscopic ellipsometer data for single oxide moisture barrier and dual oxide moisture barrier in accordance with an embodiment.

### DETAILED DESCRIPTION

In one aspect, it has been observed that thick glass encapsulants provide perovskite solar cells with good moisture barrier properties (e.g., low water vapor transmission rate, etc.). However, thick glass encapsulants may contribute significantly to the overall weight of the solar cell module. For some applications, it may be desirable to have a lighter weight module with ideally the same moisture barrier properties. It has been observed that oxide layers deposited directly on perovskite solar cells by atomic layer deposition (“ALD”) can serve as a moisture barrier. In such instances, the ALD processes are typically carried out by reactions between a single oxidizing species and a reactive organometallic precursor at a single temperature. For example, it has been observed in the organic light emitting diode (OLED) industry that very effective ALD moisture barriers have been grown using ozone oxidizing agents on other substrates. However, efforts to grow ozone oxidized barriers on perovskite solar cells have been shown to cause severe degradation of the underlying cells during the ALD process, such as degradation to the metal contacts of the solar cells (e.g., metal fingers, busbars, etc.). It has been observed that water oxidized barriers on perovskite solar cells have been shown to cause minimal damage to the underlying cells during the ALD process, yet these water oxidized barriers have not provided adequate moisture barrier properties for real-world usage.

In accordance with embodiments, perovskite solar cells are described in which ALD oxide layers, such as alumina (Al₂O₃) layers, are deposited using two different oxidizers to provide a moisture barrier which is both non-detrimental to the underlying perovskite solar cell performance and provides highly effective moisture barrier properties. First, a water oxidizer layer may be deposited on top of the perovskite solar cells. Second, an ozone oxidizer layer may then be deposited on top of the water oxidizer layer. While the initial water oxidizer layer may not provide adequate moisture barrier properties by itself, quality of the underlying perovskite cell stack-up can be preserved during the water oxidizer ALD process and the water oxidized alumina layer also serves as a protective barrier against potential damage to the cells during the ozone oxidizer ALD process. Similarly, the water oxidized ALD process can serve as a barrier to plasmas (e.g. oxygen plasma) as well as a thermally protective barrier enabling subsequent processes to be performed at higher temperatures, up to approximately 200° C. This method broadens the processing window to include alternative oxidizers (e.g. ozone or oxygen plasma) and/or higher temperatures to grow better barriers on top of perovskite semiconductors. By combining the protective qualities of the water oxidizer layers with the moisture resilience of the ozone oxidizer layers, the lightweight packaging of perovskite solar cells may be achieved.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, and “on” as used herein may refer to a relative position of one layer with respect to other layers. One layer “over” or “on” another layer or bonded “to” or in “contact” with another layer may be directly in contact with the other layer or may have one or more intervening layers. One layer “between” layers may be directly in contact with the layers or may have one or more intervening layers.

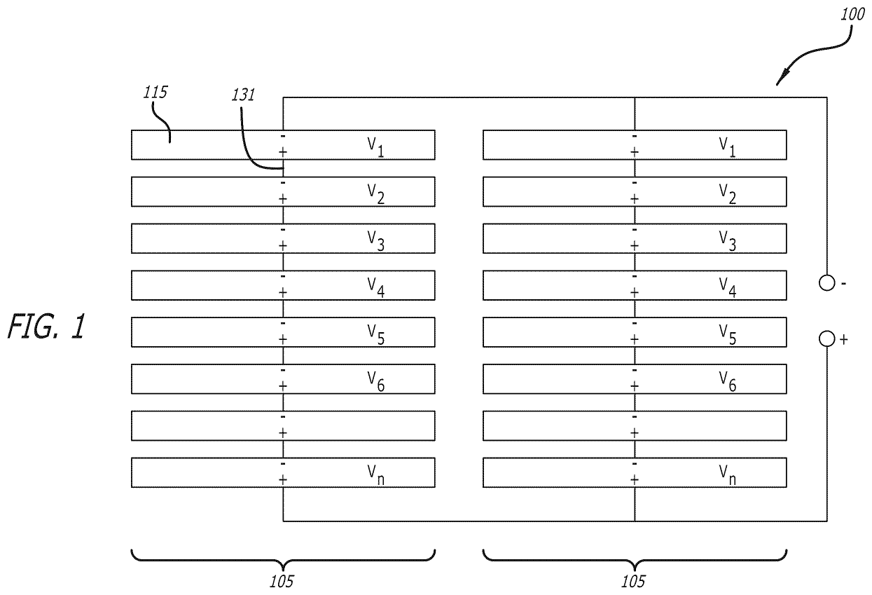

Referring now to FIG. 1, a schematic top view illustration is provided of a solar cell module in accordance with embodiments. As shown, the solar cell module 100 includes a plurality of cells 115 (also referred to as solar cells) coupled in series by interconnects 131, with the front of one cell connected to the rear of the next cell so that their voltages add (e.g., V₁, V₂, Vₙ, etc.). The plurality of cells 115 may be arranged into one or more subsets 105 (e.g., strings) coupled in parallel, which may have the effect of decreasing total module voltage. Other arrangements, in which the second row of cells are aligned half a cell length off-center of the first row, the third row a half cell length from the second, etc., are also possible. In the latter, an entire row of several cells will be connected in parallel.

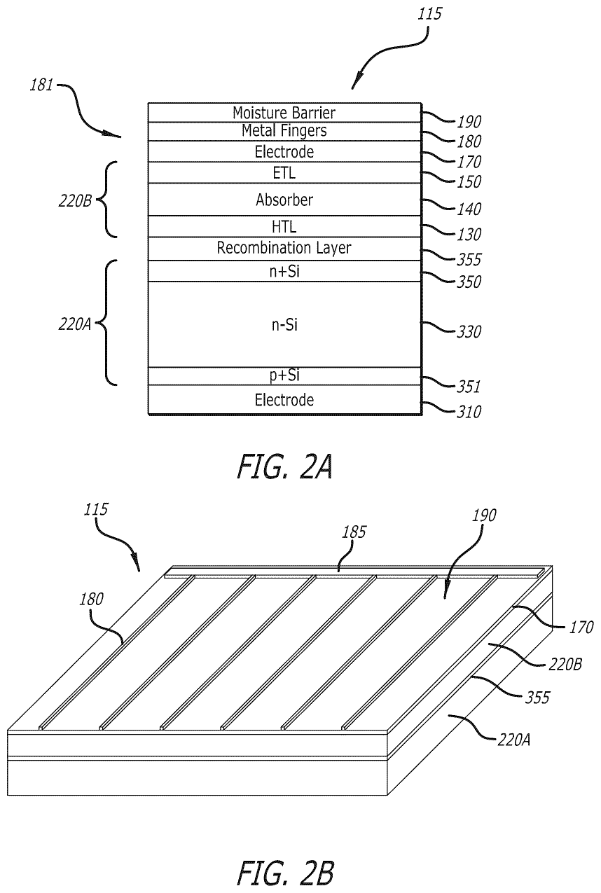

Referring now to FIGS. 2A-2B, FIG. 2A is a silicon-perovskite tandem solar cell stack-up based on an n-type silicon substrate in accordance with embodiments; FIG. 2B is a schematic perspective view of the silicon/perovskite tandem solar cell stack-up illustrated in FIG. 2A. In the following description, various layers and compositions are described for the solar cell stack-ups. It is to be appreciated that each layer may include a single layer, or multiple layers. In addition, reference to bottom or top layers herein is relative and may not be reflective of actual orientation in product. In addition, it is to be appreciated that while a specific tandem and solar cell stack-up is illustrated in FIG. 2A, that embodiments are not limited to these specific stack-ups, and that the moisture barriers described herein can be implemented into a variety of other solar cell stack-ups (e.g., single-junction solar cells, silicon-perovskite tandem solar cell stack-ups based on a p-type silicon substrate, etc.). Furthermore, in particular embodiments, the solar cell 115 may absorb light from the top side of the illustrated stack-ups similar to the embodiment illustrated in FIGS. 2A, although single-junction solar cell embodiments, for example, may absorb light from the bottom side of the stack-ups.

Referring to FIG. 2A, the tandem structure may include a perovskite subcell 220B formed over a silicon subcell 220A, which may include a doped silicon substrate 330 (e.g., n-doped substrate), a p-doped silicon layer 351 (e.g., p+ doped), and optionally an n-doped silicon layer 350 (e.g., n+ doped). In other embodiments, the silicon subcell 220A of FIG. 2A may be formed over a p-doped silicon substrate rather than the n-doped silicon, where the p-doped silicon layer 351 may be optional as opposed to the n-doped silicon layer 350 being optional. It is to be appreciated that such exemplary silicon subcells can include a variety of configurations in accordance with all embodiments, including heterojunction (HJT) design, tunnel oxide passivated contacts (TOPCon), passivated rear contact solar cell (PERC), etc.

In the example of FIG. 2A, back side contact 310 (e.g., electrode) may be formed underneath p-doped silicon layer 351, where back side contact 310 may be formed of a suitable material such as Ag, Cr, Au, Cu, Al, etc. The p-doped silicon layer 351, as well as the n-doped silicon layer 350, may be crystalline, polycrystalline (such as with TOPCon design) or amorphous (such as with an HJT design). In such an HJT design, additional intrinsic layers (e.g., intrinsic silicon) may be formed between the doped silicon substrate 330 and each of the p-doped silicon layer 351 and/or the n-doped silicon layer 350. For example, the intrinsic layers may be formed by treating the doped silicon substrate 330, such as with hydrogen plasma, where the intrinsic layer(s) may also be crystalline or amorphous. Further, a recombination layer 355 may be formed over n-doped silicon layer 350 (between silicon subcell 220A and perovskite subcell 220B), where the recombination layer 355 may be formed of a transparent conducting material, such as a transparent conductive oxides (“TCO”) or indium tin oxide (“ITO”) specifically. In addition, the recombination layer 355 may be laterally or vertically conductive.

Perovskite subcell 220B may include an absorber layer 140 and one or more transport layers. In the embodiment illustrated, perovskite subcell 220B includes hole transport layer (“HTL”) 130 over the optional recombination layer 355, and electron transport layer (“ETL”) 150 over the absorber layer 140. In each of the embodiments described with regard to FIGS. 2A-2B, specific perovskite sub-cell stack-ups may include n-p, p-n, n-i-p, or p-i-n orientations. These changes in order of layer formation can additionally change materials selection of some layers without straying from the principles of the embodiments. Thus, reference to ETL or HTL and n-doped layer or p-doped layer may be reversed in accordance with embodiments.

HTL 130 may include one or more layers formed of a metal oxide such as nickel oxide (NiOₓ) or vanadium oxide (V₂O₅), an organic polymer such as poly(triaryl amine) (PTAA), small molecules such as 2,2′,7,7′-Tetrakis[N,N-di(4-methoxyphenyl)amino]-9,9′-spirobifluorene (spiro-MeOTAD), or a “self-assembled monolayer” in which molecular assemblies can be formed spontaneously on surfaces by adsorption and then organized into large ordered domains. In one example, self-assembled monolayers can be formed where hole transporting moieties are attached to the underlying TCO or HTL layer via an acid binder group such as a phosphonic acid or carboxylic acid, although other compositions and methods of formation are contemplated. HTL 130 may additionally be doped to increase conductivity and may include a bi-layer of a metal oxide (e.g., NiOₓ) and an organic layer on top (e.g., PTAA, poly(3,4-ethylenedioxythiophene) polystyrene sulfonate (“PEDOT:PSS”), etc.).

Absorber layer 140 is located over HTL 130. The absorber layer 140 in accordance with embodiments may be formed of a perovskite material. Perovskite materials may be characterized by the formula ABX₃, with A representing a large atomic or molecular cation (e.g., Cs, methylammonium, formamidinium, etc.), with B representing a positively charged cation (e.g., metal, lead, plumbate, Sn), and X representing a negatively charged anion (e.g., halide, I, Br, Cl, etc.). Perovskite materials can also include a mixture of 2D and 3D structures in the family of A¹ₘAₙBₙ₋₁X₃ₙ₋₁ where A¹ represents a positively charged cation (e.g., butylammonium, phenethylammonium, guanidinium, etc.).

ETL 150 in accordance with embodiments can be formed of fullerenes, metal halides, tin oxide, titanium oxide, napthalene diimide and related derivatives, etc. An additional buffer layer may be included as part of or on top of ETL 150. For example, the buffer layer can physically separate the electrode layer, or top metal pattern, from the subcell, and more specifically the absorber layer. In an embodiment, the buffer layer is formed of a metal oxide material such as tin oxide, titanium dioxide, or aluminum zinc oxide (“AZO”) over a fullerene ETL 150. The buffer layer can function as a barrier layer as well as a charge transport layer. In a specific embodiment, the top electrode layer 170 is formed of a transparent conducting material. Since the lower silicon subcell 220A may be opaque, the top electrode layer 170 may be formed of a transparent conducting layer such as poly(3,4-ethylenedioxythiophene) polystyrene sulfonate (PEDOT:PSS), TCOs such as indium tin oxide (ITO), fluorine doped tin oxide (FTO), indium zinc oxide (IZO), aluminum doped zinc oxide (AZO), cadmium stannate, etc. A top metal pattern 181 may then be formed over the transparent top electrode layer 170, for example to facilitate charge transport. In an embodiment, the top metal pattern 181 is formed of a suitable material such as Ag, Cr, Au, Cu, Al, etc. The top metal pattern 181 may be formed in the shape of a plurality of metal finger 180 electrodes and optionally busbar 185 connecting the plurality of metal finger 180 electrodes so as to transport charge without overly blocking light transmission. Further, moisture barrier 190 may then be formed over top metal pattern 181.

Referring now to FIG. 2B, a schematic perspective view is shown of the silicon/perovskite tandem solar cell stack-up in FIG. 2A. As illustrated in FIG. 2B, moisture barrier 190 is located over top electrode layer 170 and top metal pattern 181, which includes the plurality of metal finger 180 electrodes connected to busbar 185. In embodiments, moisture barrier 190 is a lightweight “on-cell” encapsulation that may be employed either on its own or in combination with a lightweight/high water vapor transmission rate (“WVTR”) encapsulation, where the on-cell encapsulation may be formed by atomic layer deposition or chemical vapor deposition. As such, due to the conformal nature of ALD, moisture barrier 190 also directly contacts top electrode layer 170 and top metal pattern 181, which includes the plurality of metal finger 180 electrodes connected to busbar 185. Moisture barrier 190 may also conformally coat the edges and underside of the device. Typically, ALD processes are carried out via reaction between a single oxidizing species and a reactive organometallic precursor at a single temperature. However, the ALD process for the dual oxide moisture barrier or bilayer described herein is carried out in two operations: first, a water oxidized thin layer on top of the top electrode layer 170 and top metal pattern 181; and second, an ozone oxidized thin layer on top of the water oxidized thin layer. In this way, the dual oxide moisture barrier includes a water oxidized layer that provides effective protection to the top electrode layer 170 and top metal pattern 181, and an ozone oxidized layer that provides a moisture resilient layer to the solar cell as a whole, including perovskite subcell 220B. In some embodiments, the first and second operations may be carried out at a uniform temperature. In other embodiments, the first operation may be carried out at lower temperatures to minimize damage to the perovskite solar cell, whereas the second operation may be carried out at higher temperatures to further increase moisture resilience.

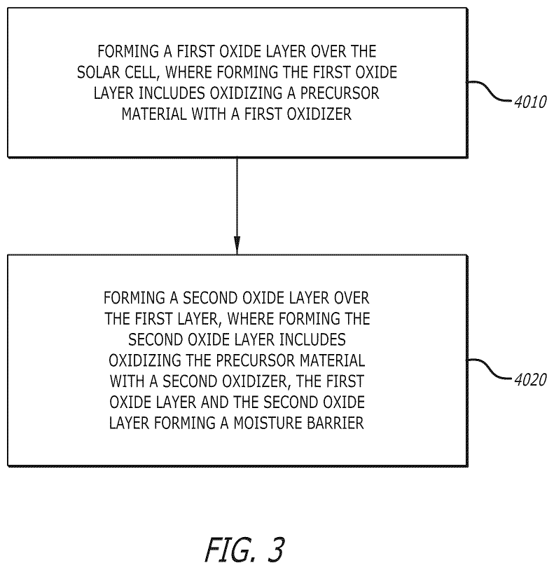

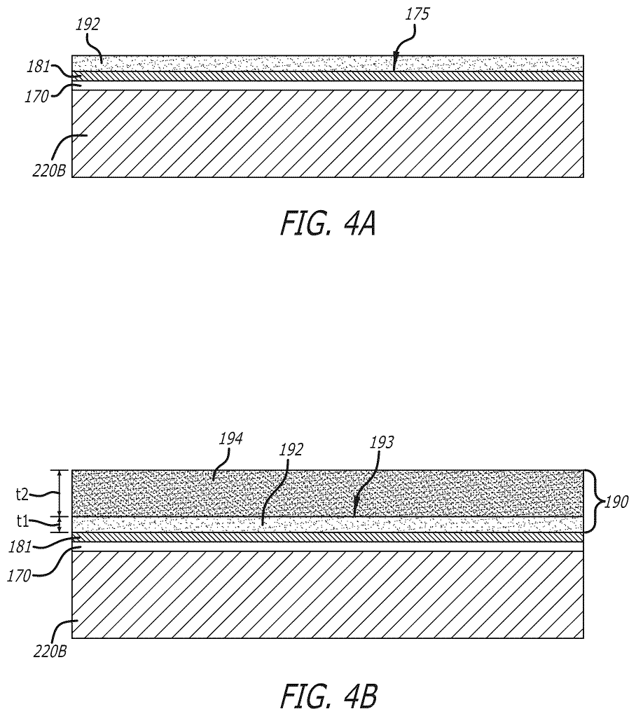

Referring now to FIG. 3 and FIGS. 4A-4B, FIG. 3 is a process flow of a method of forming a dual oxide moisture barrier in accordance with an embodiment; FIGS. 4A-4B are schematic side view illustrations of a method for forming a dual oxide moisture barrier in accordance with an embodiment. In the interest of clarity and conciseness, the method of FIG. 3 is described concurrently with the illustrations of FIGS. 4A-4B. Also, it should be noted that while the dual oxide moisture barrier in FIGS. 4A-4B is formed over a perovskite subcell, it is to be appreciated that embodiments are not limited to this specific stack-up, and that the dual oxide moisture barriers described herein can be implemented into a variety of other solar cell stack-ups (e.g., single-junction solar cells, silicon-perovskite tandem solar cell stack-ups, etc.).

As shown in FIG. 4A, at operation 4010 first oxide layer 192 may be formed over top electrode layer 170 and top metal pattern 181 of perovskite subcell 220B by atomic layer deposition. First, a hydroxylation operation may be performed so that hydroxyl groups (—OH) may “functionally activate” surface 175 of perovskite subcell 220B. In addition, an initial conditioning operation may be performed to stabilize the pressure and temperature of the ALD chamber as well as the temperature of the precursors or reactants. Surface 175 may then be exposed to a precursor or reactant. Precursors may include metal-organic material (e.g., trimethylaluminum (“TMA”), dimethylaluminum isopropoxide (“DMAI”), etc.) or any other suitable material for the deposition of thin films on solar cell surfaces to provide moisture barrier properties, In one embodiment, a TMA precursor is pulsed into the ALD chamber. During the pulsing period, TMA dissociatively chemisorbs on the subcell surface, where a two-operation chemical reaction occurs with two separate activation energies. First, the TMA adsorbs to surface 175 and interacts as a Lewis acid base complex with an exothermic energy of interaction. Second, an “exchange” reaction with an additional exothermic component occurs since surface 175, which had been terminated with —OH, now exchanges the —OH terminations with —CH₃ terminations, where the H is removed as the byproduct CH₄. After all the active —OH sites have reacted with TMA, the reaction achieves saturation. The surface is now CH₃ terminated, which blocks or passivates the surface to any further reactions. The CH₄ byproduct and any excess TMA is then purged during a first removal period (e.g., N₂ purge). This first half reaction may be summarized as equation (1):

$$OH + {Al ( {CH}_{3} )}_{3} \to {{AlO ( {CH}_{3} )}_{2} + CH}_{4} . \qquad ( 1 )$$

The dissociative chemisorption of TMA leaves a surface covered with AlCH₃, where the passivating —CH₃ ligands provide a new functionally activated surface. The surface is then exposed to water vapor, when another two-operation chemical reaction occurs with two separate activation energies. First, the HOH adsorbs to the surface and interacts as a Lewis acid base complex with an exothermic energy of interaction. Second, an exchange reaction with an additional exothermic component occurs since surface, which had been terminated with —CH₃, now exchanges the —CH₃ terminations with —OH terminations, where the —CH₃ is removed as the byproduct CH₄. After all the HOH reacts with all accessible CH₃ sites, the reaction achieves saturation and the —OH acts as passivating ligands to block the deposition of additional HOH reactant. The byproduct CH₄ and the unreacted H₂O may then be purged during a second removal period. This second half reaction for the hydroxylated Al₂O₃ surface may be summarized as equation (2):

$${Al ( {CH}_{3} )}_{3} + HOH \to {Al}_{2} {O}_{3} + {CH}_{4} . \qquad ( 2 )$$

This sequential process is repeated to build the desired film thickness.

As shown in FIG. 4B, at operation 4020 second oxide layer 194 may be formed over first oxide layer 192 by atomic layer deposition. During the ALD process, the passivating —OH ligands from the deposition of first oxide layer 192 provide a functionally activated surface, such as surface 193 in FIG. 4B. Similar to the reaction described at operation 4010, in an embodiment a TMA precursor may be pulsed into the ALD chamber, where the TMA adsorbs to surface 193 and interacts as a Lewis acid base complex with an exothermic energy of interaction, and —OH terminations exchange with —CH₃ terminations with an additional exothermic component, where the H is removed as the byproduct CH₄. After all the active —OH sites have reacted with TMA, the reaction achieves saturation. The surface is now CH₃ terminated, which blocks or passivates the surface to any further reaction with. The CH₄ byproduct is then purged during a first removal period. This first half reaction may be summarized as equation (3):

$$OH + {Al ( {CH}_{3} )}_{3} \to {{AlO ( {CH}_{3} )}_{2} + CH}_{4} . \qquad ( 3 )$$

The dissociative chemisorption of TMA leaves the surface covered with AlCH₃, where the passivating —CH3 ligands provide a new functionally activated surface. The surface is then exposed to an O₃ oxidizer, where another two-operation chemical reaction occurs with two separate activation energies. First, the O₃ adsorbs to the surface and interacts as a Lewis acid base complex with an exothermic energy of interaction. Second, an exchange reaction with an additional exothermic component occurs since surface 193, which had been terminated with —CH₃, now exchanges the —CH₃ terminations with —OH terminations, where the —CH₃ is removed as H, C and O containing byproducts. After all the O₃ reacts with all accessible CH₃ sites, the reaction achieves saturation and the —OH acts as passivating ligands to block the deposition of additional O₃ reactant. The byproduct H, C, O containing byproducts and the unreacted O₃ may then be purged during a second removal period. This second half reaction may be summarized as equation (4):

$${Al ( {CH}_{3} )}_{3} + {O}_{3} \to {Al}_{2} {O}_{3} + H , C , O containing byproducts . \qquad ( 4 )$$

This constitutes one cycle of the process for the second oxide layer 194, where the number of cycles may be adjusted to the desired film thickness, where the thickness of second oxide layer 194 may vary from the thickness of first oxide layer 192. In one embodiment, the thickness of second oxide layer 194 can be at least two or three times greater than the thickness of first oxide layer 192, although other thickness ratios are contemplated. For example, in FIG. 4B, first oxide layer 192 has a thickness t1, and second oxide layer 194 has a thickness t2, where t1 may be approximately 20 nm and t2 may be approximately 80 nm, although other thicknesses are contemplated based on the desired properties of the bilayer. In this way, the thickness of the water oxidized layer (e.g., first oxide layer 192) may relate to its function as a protective barrier against potential damage to the solar cells during the deposition of the ozone oxidized layer (e.g., second oxide layer 194). Further, the thickness of the ozone oxidized layer may relate to its function as a moisture resilient layer. For example, such moisture resilient properties of the ozone oxidized layer have been observed for other semiconductor materials, such as molybdenum disulfide, where using ozone as an oxidizer enhances Al₂O₃ film coverage and uniformity since, unlike water, ozone readily decomposes into molecular O₂ and monatomic O upon reaching the surface, which may accelerate TMA nucleation. This may result in producing a lower defect-state density and related defect states in the deposited ALD films.

It is to be appreciated that the above description related to TMA precursor and reaction kinetics is exemplary, and that embodiments may also be practiced with alternative precursors and reaction kinetics to form a dual oxide moisture barrier with both water oxidized and ozone oxidized layers.

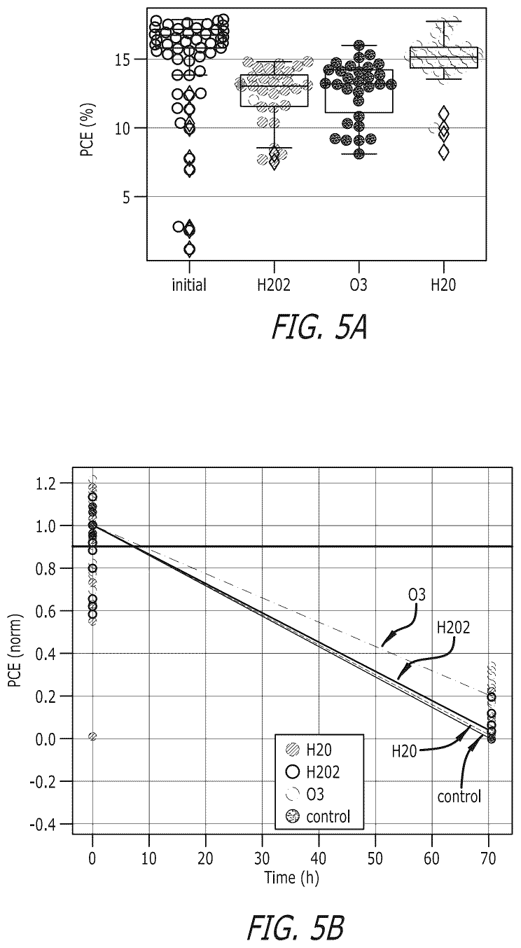

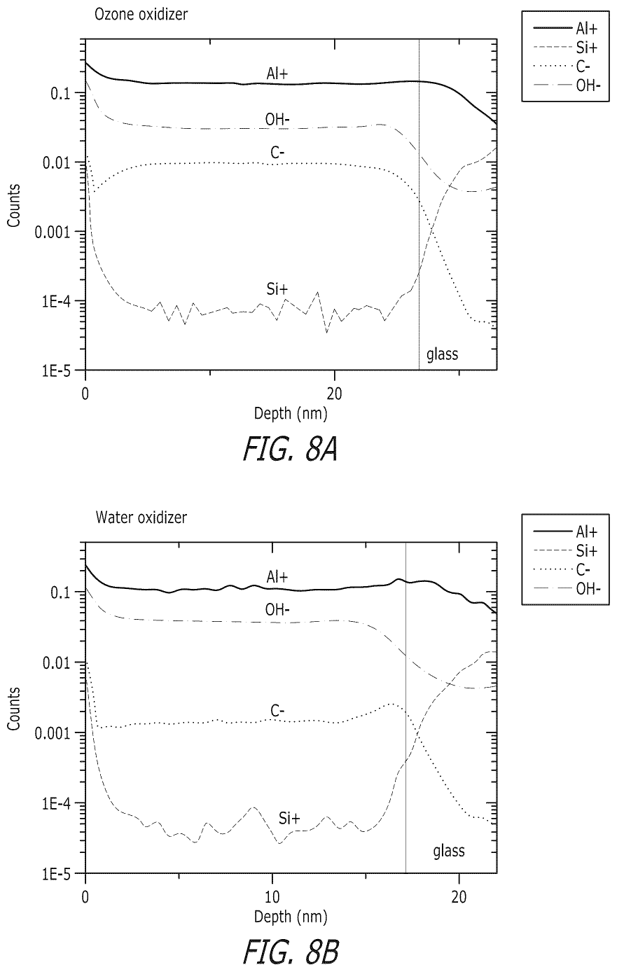

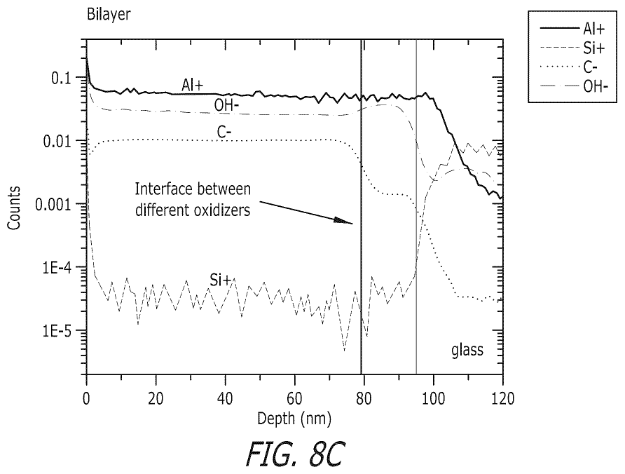

In order to demonstrate effectiveness of the dual oxide moisture barrier in accordance with embodiments, various solar cell and oxide layer test specimens were prepared to compare the performance and composition of single oxide moisture barrier layers and dual oxide moisture barriers. In particular, the perovskite solar cell specimens included perovskite subcells (similar to perovskite subcell 220B described in FIGS. 2A-2B) grown over glass substrates, as well as electrode layers and metal layers formed over the perovskite subcells (similar to top electrode layer 170 and top metal pattern 181 described in FIGS. 2A-2B). After formation of the single oxide moisture barrier and dual oxide moisture barrier over the electrode and metal layers, perovskite solar cell performance was measured with initial power conversion efficiency (“PCE”), damp heat testing and visual inspection, as described in FIGS. 5A-5B, FIGS. 6A-6B and FIGS. 7A-7C below. Further, compositional signatures of the single oxide moisture barrier layers and dual oxide moisture barrier formed over glass substrates were also measured using time-of-flight secondary ion mass spectrometry (ToF-SIMS) and variable angle spectroscopic ellipsometry (VASE), as described in FIGS. 8A-8C, FIGS. 9A-9B and FIGS. 10A-10D below.

FIGS. 5A-5B relate to single oxide moisture barrier specimens. FIG. 5A shows a graph that illustrates the loss of initial power conversion efficiency (“PCE”) for perovskite solar cells with different single oxidizer ALD layers. The PCE represents the conversion ratio of incident power from light energy to usable electrical power. To determine the PCE, a series of voltages are applied to the solar cell while under illumination with the output current being measured at each voltage step, resulting in an I-V curve from which the PCE may be derived. Single oxide moisture barrier specimens were prepared by atomic layer deposition on perovskite solar cells. Three perovskite solar cell specimens included moisture barriers deposited using an H₂O₂ oxidizer, an O₃ oxidizer, and an H₂O oxidizer, respectively. Further, a specimen was prepared without any moisture barrier over the perovskite solar cell to provide the “initial” PCE measurements. It was observed that the perovskite solar cell performance degraded for the H₂O₂ and O₃ oxidizer specimens, as indicated by the loss in PCE as compared to the initial PCE. No such loss in initial PCE was observed by the H₂O oxidizer specimens, suggesting that the H₂O oxidizer may be deposited without causing damage to the perovskite solar cells.

FIG. 5B shows a graph that illustrates the results of a damp heat test for perovskite solar cells with different single oxide moisture barriers. The damp heat test is a reliability test that simulates the effects of heat and condensation on a solar cell. Single oxide moisture barrier specimens were prepared by atomic layer deposition on perovskite solar cells. The three perovskite solar cell specimens included moisture barriers deposited using an H₂O₂ oxidizer, an O₃ oxidizer, and an H₂O oxidizer, respectively. Further, a control specimen was prepared without any moisture barrier on the perovskite solar cell. The damp heat test for each specimen was performed by applying 45° C. heat with a relative humidity of 85% for an uninterrupted cycle of 70 hours. As indicated by the graph in FIG. 5B, near full degradation (90%) was observed for each specimen.

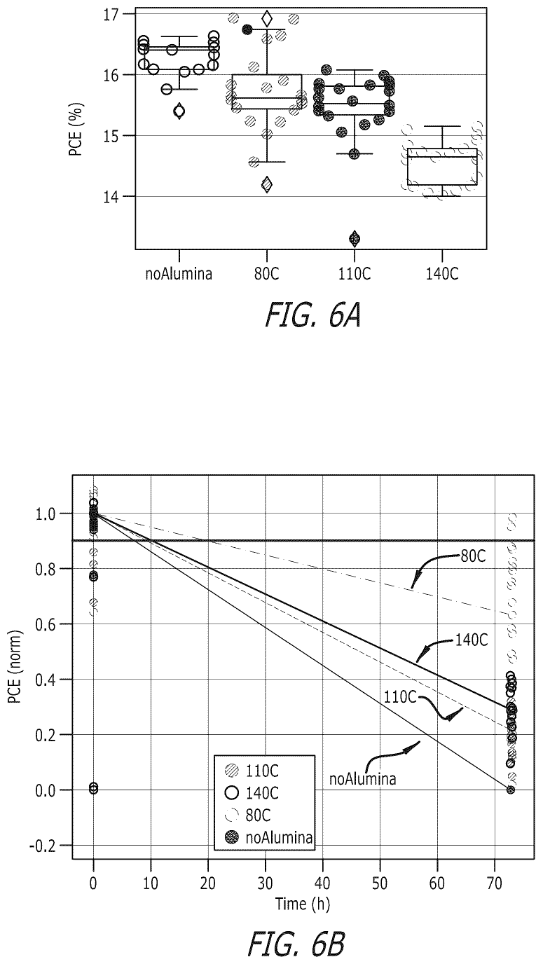

FIGS. 6A-6B relate to dual oxide moisture barrier specimens. FIG. 6A shows a graph that illustrates the loss of initial PCE for perovskite solar cells with a dual oxide moisture barrier in accordance with embodiments. The dual oxide moisture barrier layer specimens were prepared by atomic layer deposition on perovskite solar cells, where the moisture barrier included an initial water oxidized TMA layer followed by an ozone oxidized TMA layer. Further, the dual oxide moisture barrier was deposited at different temperatures for each specimen. More specifically, the dual oxide moisture barrier was deposited at 80° C. for the first specimen, 110° C. for the second specimen, and 140° C. for the third specimen. Further, a specimen was prepared without any moisture barrier on the perovskite solar cell to provide the “initial” PCE measurements. It was observed that the dual oxide moisture barrier deposited at 80° C. showed minimal initial PCE loss when compared to the dual oxide moisture barriers deposited at 110° C. and 140° C., suggesting that dual oxide moisture barrier formed at 80° C. may minimize damage to the electrode layers, metal layers, and underlying perovskite subcells.

FIG. 6B shows a graph that illustrates the results of a damp heat test for perovskite solar cells with a dual oxide moisture barrier in accordance with an embodiment. The dual oxide moisture barrier specimens were prepared by atomic layer deposition on perovskite solar cells, where the moisture barrier included an initial water oxidized TMA layer followed by an ozone oxidized TMA layer. Further, the dual oxide moisture barrier was deposited at different temperatures for each specimen. More specifically, the dual oxide moisture barrier was deposited at 80° C. for the first specimen, 110° C. for the second specimen, and 140° C. for the third specimen. Further, a control specimen was prepared without any moisture barrier on the perovskite solar cell. The damp heat test for each specimen was performed by applying 45° C. heat with a relative humidity of 85% for an uninterrupted cycle of 70 hours. As indicated by the graph in FIG. 6B, an approximately 30% loss in PCE was observed for the dual oxide moisture barrier specimen deposited at 80° C., as opposed to the approximately 75% loss in PCE observed for the dual oxide moisture barrier specimens deposited at 110° C. and 140° C.

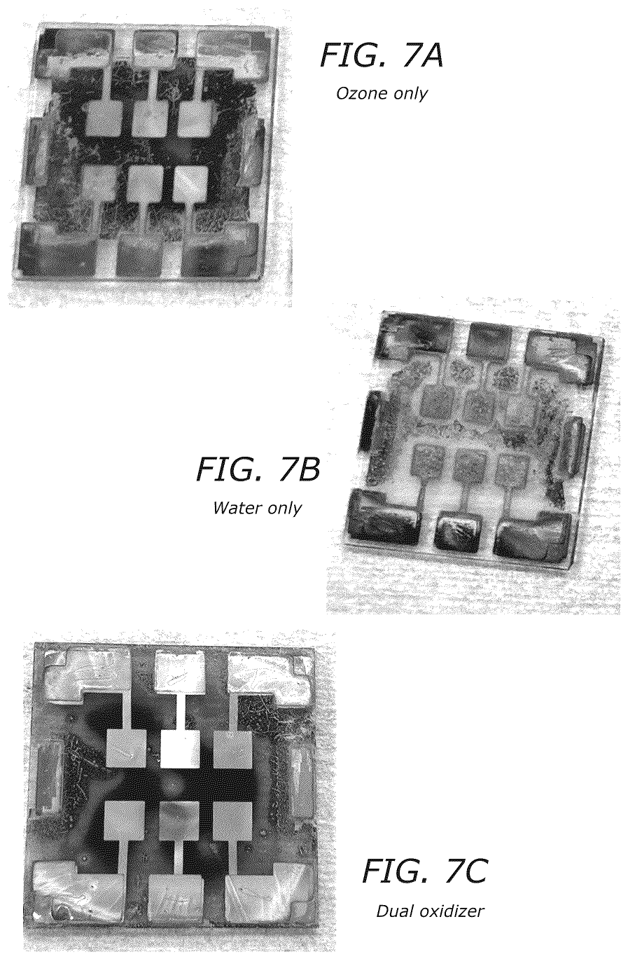

FIGS. 7A-7C show photographs of perovskite solar cell specimens with varying moisture barriers. The three perovskite solar cell specimens included moisture barriers deposited using an ozone oxidizer (FIG. 7A), a water oxidizer (FIG. 7B), and a dual oxidizer (water and ozone) in accordance with embodiments (FIG. 7C), respectively. A damp heat test for each specimen was performed by applying 45° C. heat with a relative humidity of 85% for an uninterrupted cycle of 70 hours. Degradation of the solar cell stack-ups can be visually detected by hazing of the metal electrodes (which should shine) and hazing and/or cracking of the underlying perovskite solar cell (which is translucent). As observed in the photographs, the damp heat test resulted in significant degradation of both the electrode and perovskite solar cell for the ozone only oxidizer specimen (FIG. 7A) and the water only oxidizer specimen (FIG. 7B), whereas the dual oxide moisture barrier specimen (FIG. 7C) resulted in significantly less degradation of both the metal electrodes and perovskite solar cell.

The above results described with regard to FIGS. 5A-7C illustrated potential performance characteristics of the dual oxide moisture barrier. In the following description various specimens are prepared and tested in order to illustrate compositional signatures of the dual oxide moisture barrier.

FIGS. 8A-8C show the time-of-flight secondary ion mass spectrometry (“ToF-SIMS”) depth profiles for aluminum oxide samples formed over a glass substrate with the single ozone oxidized layer (FIG. 8A), the single water oxidized layer (FIG. 8B) and the dual oxide moisture barrier in accordance with embodiments (FIG. 8C). ToF-SIMS is an imaging mass spectrometry technique that obtains isotopic, elemental, and molecular information from the surface of solid samples, where a pulsed “primary” ion beam bombards the surface and induces a collision cascade, which liberates “secondary” ions that are then sent to a time-of-flight mass analyzer for detection. In addition to ToF-SIMS data related to aluminum oxide, FIGS. 8A-8C also include data related to silicon to show the presence of the glass substrate (gray area). A comparison of the depth profiles for FIGS. 8A-8C shows different thickness for each sample. For example, the thickness of the single ozone oxidizer layer in FIG. 8A is between 20-30 nm, the thickness of the single water oxidizer layer in FIG. 8B is between 15-20 nm, and the thickness of the bilayer in FIG. 8C is between 90-100 nm, where the water oxidizer layer (over the glass substrate) is approximately 15 nm thick and the ozone oxidizer layer (over the water oxidizer layer) is approximately 80 nm thick. In addition, a comparison of the depth profile for FIGS. 8A-8B shows a clear difference in —OH and carbon count between the ozone oxidized layer and the water oxidized layer. In particular, the ozone oxidized layer in FIG. 8A has a lower —OH count (approximately 0.03 counts) and higher carbon count (approximately 0.009 counts) as compared to the water oxidized layer in FIG. 8B, which has slightly a higher —OH count (approximately 0.04 counts) and significantly lower carbon count (approximately 0.001 counts). These trends can be observed in the —OH and carbon counts for the bilayer in FIG. 8C. For example, along the approximately 0-80 nm depth profile in FIG. 8C, the —OH count (approximately 0.03 counts) and carbon count (approximately 0.01 counts) correspond to the —OH and carbon counts observed for the ozone oxidized single layer in FIG. 8A. Further, along the approximately 80-95 nm depth profile in FIG. 8C, the —OH counts (approximately 0.04 counts) and carbon count (approximately 0.001 counts) correspond to the —OH and carbon counts observed for the water oxidized single layer in FIG. 8B. Therefore, the count data observed in FIGS. 8A-8C indicate the presence of two distinct alumina layers in accordance with embodiments.

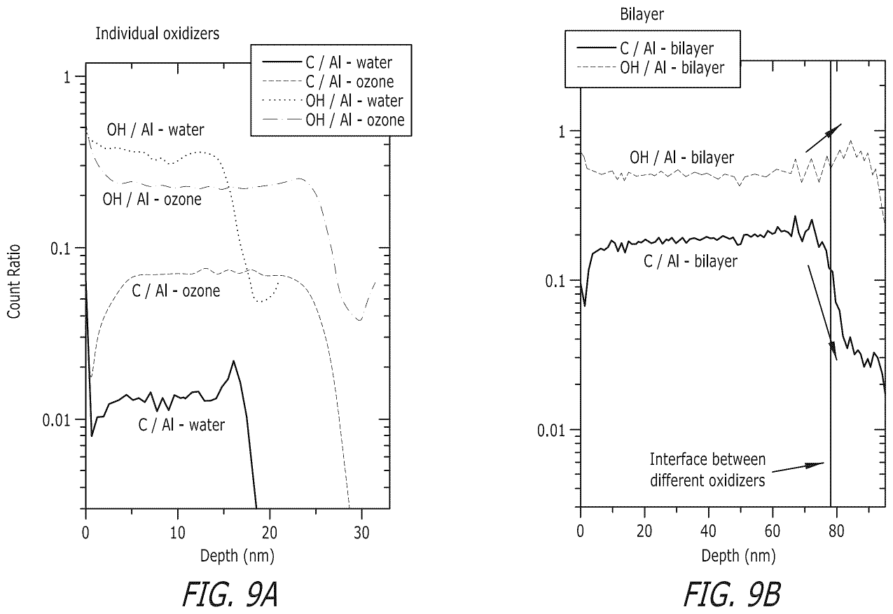

FIGS. 9A-9B show the ToF-SIMS data related to the count ratios for aluminum oxide samples formed over glass substrates with the respective single oxidize layers (FIG. 9A) and the dual oxide moisture barrier in accordance with embodiments (FIG. 9B). The data was collected with a 30 KeV Bi₃⁺ primary ion beam (1 pA pulsed current) rastered over a 50×50 micron area. Sputter depth profiling was accomplished with a 1 KeV Cs beam (5 nA current) rastered over a 150×150 micron area. The data was collected in both positive and negative SIMS polarities, otherwise with identical beam conditions. The analysis cycle time was 100 microseconds, allowing analysis of species between 0 and 930 mass/charge ratio. FIG. 9A establishes a baseline for the count ratios for the respective single oxide moisture barrier layers. In particular, the ozone oxidized layer in FIG. 9A has a lower —OH/Al ratio (approximately 0.25 count ratio) and higher carbon/Al ratio (approximately 0.07 count ratio) as compared to the water oxidized layer in FIG. 9A, which has slightly a higher —OH/Al ratio (approximately 0.4 count ratio) and significantly lower carbon/Al ratio (approximately 0.015 count ratio). These trends can be observed in the —OH/Al and carbon/Al ratios for the bilayer in FIG. 9B. For example, along the approximately 0-80 nm depth profile in FIG. 9B, the —OH/Al ratio (approximately 0.5 count ratio) and carbon/Al ratio (approximately 0.2 count ratio) correspond to the difference in —OH/Al and carbon/Al ratios observed for the ozone oxidizer single layer in FIG. 9A. Further, along the approximately 80-95 nm depth profile in FIG. 9B, the —OH/Al ratio (approximately 0.8 count ratio) and carbon/Al ratio (approximately 0.03 count ratio) correspond to the difference in —OH/Al and carbon/Al ratios observed for the water oxidized single layer in FIG. 9A. In further reference to FIG. 9B, the pronounced change in count ratios at approximately 80 nm marks the interface between the different oxidizer layers in the bilayer. Therefore, the count ratio data observed in FIGS. 9A-9B indicate the presence of two distinct alumina layers in accordance with embodiments.

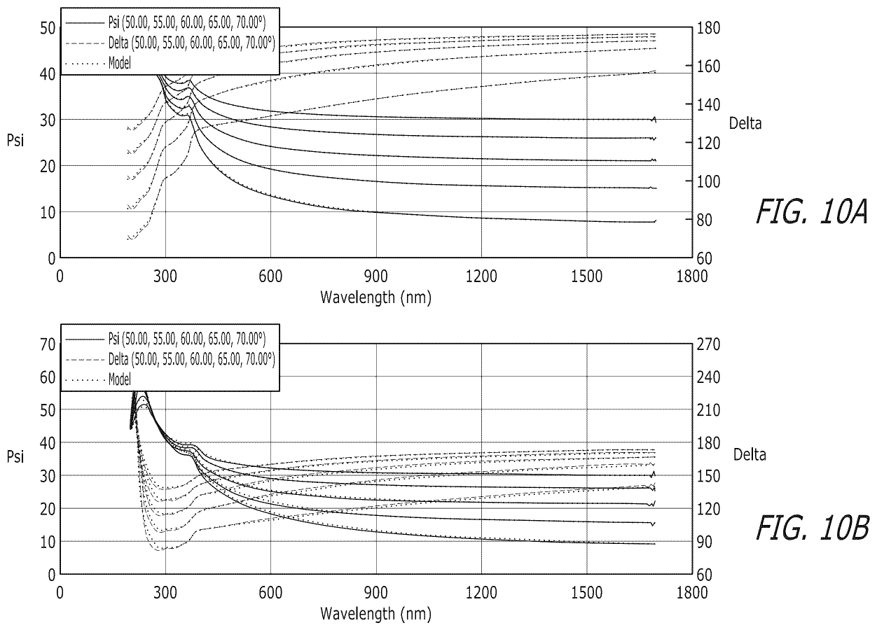

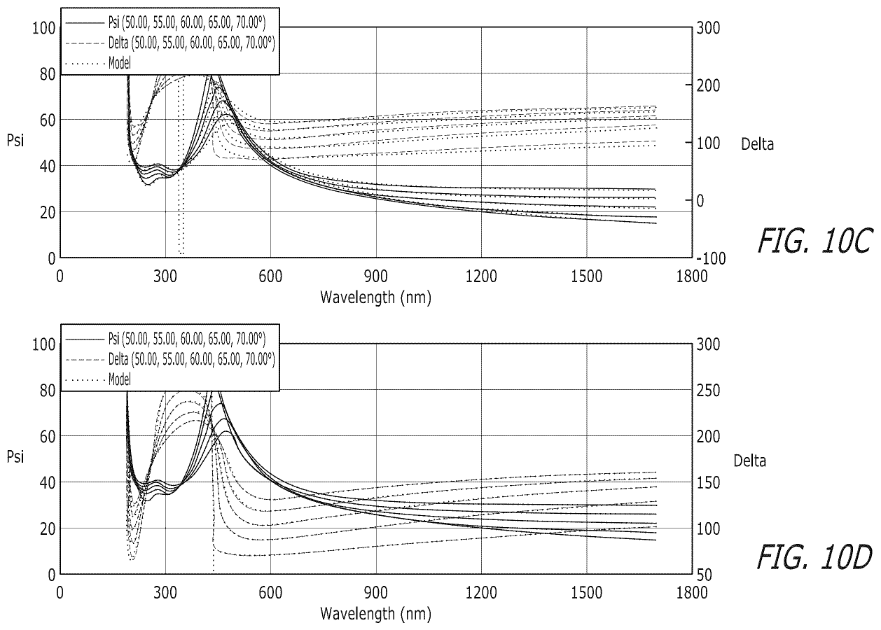

FIGS. 10A-10D shows a summary of the variable angle spectroscopic ellipsometer (“VASE”) data for aluminum oxide samples with a water oxidized single layer (FIG. 10A), an ozone oxidized single layer (FIG. 10B), and a dual oxide moisture barrier in accordance with embodiments (FIGS. 10C-10D). The VASE measurements were made by analyzing polarized light reflected from the sample surface and fitting the measured data to a model. In FIG. 10A, the fit for the data from the water oxidized single layer sample yielded a mean squared error (“MSE”) of 4.4. In FIG. 10B, the fit for the data from the ozone oxidized single layer sample yielded an MSE of 18.5. In FIG. 10C, the dual oxide moisture barrier sample data was fit as a single layer and yielded an MSE of 51.4, which is a poor fit. In FIG. 10D, the dual oxide moisture barrier sample data was fit using the parameters from the fitted water oxidized layer parameters in FIG. 10A and the fitted ozone oxidized layer parameters in FIG. 10B, yielding an MSE of 24.9. As such, the better fit observed in FIG. 10D as compared to FIG. 10C indicates the presence of two discrete layers in the dual oxide moisture barrier sample. Therefore, the VA SE data has a lower MSE fit for the bi-modal layer than the single modal layer, which indicates that utilizing dual oxidizers during the ALD process yields distinct alumina layers in accordance with the embodiments described.

In utilizing the various aspects of the embodiments, it would become apparent to one skilled in the art that combinations or variations of the above embodiments are possible for forming a dual oxide moisture barrier. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A method for processing a solar cell comprising:
forming a first oxide layer over the solar cell, wherein forming the first oxide layer includes oxidizing a precursor material with a first oxidizer; and
forming a second oxide layer over the first oxide layer, wherein forming the second oxide layer includes oxidizing the precursor material with a second oxidizer;
wherein the first oxide layer and the second oxide layer form a moisture barrier.

2. The method of claim 1, wherein the solar cell includes a silicon subcell stacked in tandem with a perovskite subcell, the perovskite subcell being located over the silicon subcell.

3. The method of claim 2, wherein the solar cell further includes a top electrode layer formed over the perovskite subcell, and a top metal pattern formed over the top electrode layer.

4. The method of claim 3, wherein the first oxide layer directly contacts the top electrode layer and the top metal pattern.

5. The method of claim 1, wherein the precursor material comprises trimethylaluminum (TMA).

6. The method of claim 1, wherein the first oxidizer comprises water.

7. The method of claim 1, wherein the second oxidizer comprises ozone.

8. The method of claim 1, wherein forming the first oxide layer and the second oxide layer includes depositing the first oxide layer and the second oxide layer by atomic layer deposition or chemical vapor deposition.

9. The method of claim 1, wherein a first thickness of the first oxide layer is less than a second thickness of the second oxide layer.

10. The method of claim 1, wherein a first —OH count of the first oxide layer is greater than a second —OH count of the second oxide layer, and a first carbon count of the first oxide layer is less than a second carbon count of the second oxide layer.

11. The method of claim 10, wherein the first —OH count of the first oxide layer is approximately 0.04 counts and the second —OH count of the second oxide layer is approximately 0.03 counts, and the first carbon count of the first oxide layer is approximately 0.001 counts and the second carbon count of the second oxide layer is approximately 0.01 counts.

12. The method of claim 1, wherein a first —OH-to-Al count ratio of the first oxide layer is greater than a second —OH-to-Al count ratio of the second oxide layer, and a first carbon-to-Al count ratio of the first oxide layer is less than a second carbon-to-Al count ratio of the second oxide layer.

13. A solar cell comprising:
a first oxide layer formed over the solar cell; and
a second oxide layer formed over the first oxide layer;
wherein the first oxide layer and the second oxide layer form a moisture barrier.

14. The solar cell of claim 13, wherein the solar cell includes a perovskite subcell, a top electrode layer formed over the perovskite subcell, and a top metal pattern formed over the top electrode layer.

15. The solar cell of claim 14, wherein the solar cell further includes a silicon subcell stacked in tandem with the perovskite subcell, the perovskite subcell being located over the silicon subcell.

16. The solar cell of claim 14, wherein the first oxide layer directly contacts the top electrode layer and the top metal pattern.

17. The solar cell of claim 13, wherein a first thickness of the first oxide layer is less than a second thickness of the second oxide layer.

18. The solar cell of claim 13, wherein a first —OH count of the first oxide layer is greater than a second —OH count of the second oxide layer, and a first carbon count of the first oxide layer is less than a second carbon count of the second oxide layer.

19. The solar cell of claim 18, wherein the first —OH count of the first oxide layer is approximately 0.04 counts and the second —OH count of the second oxide layer is approximately 0.03 counts, and the first carbon count of the first oxide layer is approximately 0.001 counts and the second carbon count of the second oxide layer is approximately 0.01 counts.

20. The solar cell of claim 13, wherein a first —OH-to-Al count ratio of the first oxide layer is greater than a second —OH-to-Al count ratio of the second oxide layer, and a first carbon-to-Al count ratio of the first oxide layer is less than a second carbon-to-Al count ratio of the second oxide layer.
